(19) United States
(12) Patent Application Publication
(10) Pub. No.: US 2026/0197961 A1
(43) Pub. Date: Jul. 9, 2026

(54) BUFFER DEVICE AND SLIDE RAIL ASSEMBLY USING SAME

(71) Applicant: Nan Juen International Co., Ltd., Taoyuan City (TW)

(72) Inventors: Kuo-Chin LAI, Taoyuan City (TW); Jia-Hung TSAI, Taoyuan City (TW)

(21) Appl. No.: 19/356,138

(22) Filed: Oct. 12, 2025

(30) Foreign Application Priority Data
Jan. 7, 2025 (TW) 114100778

(51) Int. Cl. H05K 7/14; A47B 96/02; F16C 29/02

(52) U.S. Cl. CPC H05K 7/1489; A47B 96/025; F16C 29/02; A47B 2220/0022

(57) ABSTRACT

A slide rail assembly includes a first slide rail, a second slide rail, and a buffer device including a base, a slide, a movable member and a displacement member. When the second slide rail retracts relative to the first slide rail, the second slide rail abuts against the slide, which compresses the displacement member, so that the slide and the base are in a retracted state, and through the thrust of the displacement member and the movable member, the guide features of the base are supported to allow the second slide rail to move slowly; when the second slide rail expands and displaces relative to the first slide rail, the slide and the base are transformed from the retracted state to the expanded state, and the displacement member extends, driving the slide to separate from the second slide rail.

### BACKGROUND OF THE INVENTION

### 1. Field of the Invention

The present invention relates to a slide rail assembly, particularly one suitable for industrial server cabinets and chassis, which utilizes a buffer device to allow one rail to move slowly relative to the other rail during its retraction and displacement.

### 2. Description of the Related Art

In the existing industrial server cabinet and chassis, one slide rail of the slide rail assembly is installed on the chassis, and the other slide rail of the slide rail assembly is installed on the cabinet. During the retraction and displacement process of one slide rail relative to the other slide rail, a buffer force of a buffer device, such as a device composed of a hydraulic rod, is applied, so that the slide rail has a slow displacement stroke to the end point before the retraction and displacement reaches the end point of the stroke. However, the aforementioned slow displacement method causes one slide rail to have a slow displacement stroke when it is extended relative to the other slide rail, which may cause the user to apply excessive force to the chassis on the slide rail, causing the slide rail to separate from the other slide rail and the chassis to fall out of the cabinet. Therefore, how to solve the problem of a slide rail having a slow displacement stroke when it is displaced relative to another slide rail is the direction that relevant industries engaged in this industry are eager to research and improve.

However, the components of the buffer device are often dispersedly mounted on the slide rail, another slide rail, or a bracket. For example, the buffer device composed of a damping gear and a rack is installed on different slide rails and the bracket respectively, resulting in low installation efficiency and difficult maintenance and replacement. Therefore, how to solve the problems of low installation efficiency and difficult maintenance and replacement is the direction that relevant industries engaged in this industry are eager to research and improve.

### SUMMARY OF THE INVENTION

The present invention provides a buffer device, which comprises a base, a slide coupled to the base and provided with a plurality of guide features on at least one side between two ends thereof, a displacement member set between the base and the slide, and at least one movable member located on one side of the slide, wherein when the slide is displaced in a first direction by a force, the slide compresses the displacement member, and the slide and the base are in a retracted state, and the slide is displaced slowly by a thrust of the displacement member and the at least one movable member against the plurality of guide features; when the slide is extended and pushed by the displacement member, the slide and the base are put into an expanded state through the pushing force of the displacement member, so that the slide is quickly displaced in a second direction opposite to the first direction.

The present invention also provides a slide rail assembly, which comprises a first slide rail and a second slide rail displaceable relative to the first slide rail, and a buffer device, which comprises a base, a slide, at least one movable member and a displacement member, the base and the slide being coupled to each other, the base and the at least one movable member being respectively installed at one end of the first slide rail, the slide comprising a plurality of guide features on at least one side between two ends thereof, the displacement member being set between the base and the slide, wherein: when the second slide rail moves relative to the first slide rail in a first direction, the second slide rail abuts against the slide to displace the slide, so that the slide drives the displacement member to compress, the slide and the base are in a retracted state, and the second slide rail is displaced slowly by a thrust of the displacement member and the at least one movable member against the plurality of guide features; when the second slide rail is displaced relative to the first slide rail in a second direction opposite to the first direction, the displacement member is extended, so that the slide and the base are in an expanded state, and the second slide rail is separated from the slide.

Preferably the at least one movable member each is a damping gear, the plurality of guide features are a series of teeth, and the at least one damping gear engages with the series of teeth.

Preferably the least one movable member each is a rolling bearing, the plurality of guide features are arc convex blocks, and the at least one rolling bearing presses and engages the plurality of arc convex blocks.

Preferably the at least one movable member each is a component having one of the functions of rotating rapidly in the forward direction or rotating slowly in the reverse direction.

Preferably the displacement member is selectively one of a spring, a hydraulic rod or a pneumatic rod.

Preferably the base comprises at least one fixing portion extending outwardly from at least one of two opposite lateral sides thereof, a first end portion, an opposing second end portion, a first fixing hole located on the first end portion, a second fixing hole located on the second end portion, and a receiving groove extending from the second end portion toward the first end portion for the front end of the displacement member to be disposed.

Preferably the slide further comprises a third end portion and a fourth end portion on two sides thereof, two support bars respectively bent from the third end portion and the fourth end portion in the same direction, and a recessed support portion respectively provided at the bends between the third end portion and the fourth end portion.

Preferably the buffer device further comprises a hollow groove disposed between the third end portion and the fourth end portion, and an elastic space formed below the hollow groove for the displacement member to be disposed.

Preferably the slide further comprises a first connecting portion extending from the third end portion toward the fourth end portion and located below the hollow groove; the base further comprises a second connecting portion provided in the receiving groove corresponding to the first connecting portion; said displacement member has a front end thereof set at the second connecting portion and an opposing rear end thereof set at the first connecting portion so that the displacement member to compress and stretch in the receiving groove and the elastic space.

Preferably the buffer device further comprises a locking member passed through the hollow groove and installed on the base to restrict the displacement member to the elastic space.

### BRIEF DESCRIPTION OF THE DRAWINGS

FIG. 1 is a three-dimensional external view of the slide rail assembly of the present invention.

FIG. 2 is an exploded view of the slide rail assembly of the present invention.

FIG. 3 is an exploded view of the buffer device of the present invention.

FIG. 4 is an exploded view of the buffer device of the present invention viewing from another angle.

FIG. 5 is a schematic diagram of the buffer device of the present invention in a retracted state.

FIG. 6 is a schematic diagram illustrating the operation of the buffer device of the present invention.

FIG. 7 is a schematic diagram of the buffer device of the present invention in an expanded state.

FIG. 8 is a schematic cross-sectional view of the buffer device of the present invention in an expanded state.

FIG. 9 is a schematic diagram of the slide rail assembly of the present invention being folded.

FIG. 10 is a schematic diagram of the slide rail assembly of the present invention being expanded.

### DETAILED DESCRIPTION OF THE PREFERRED EMBODIMENT

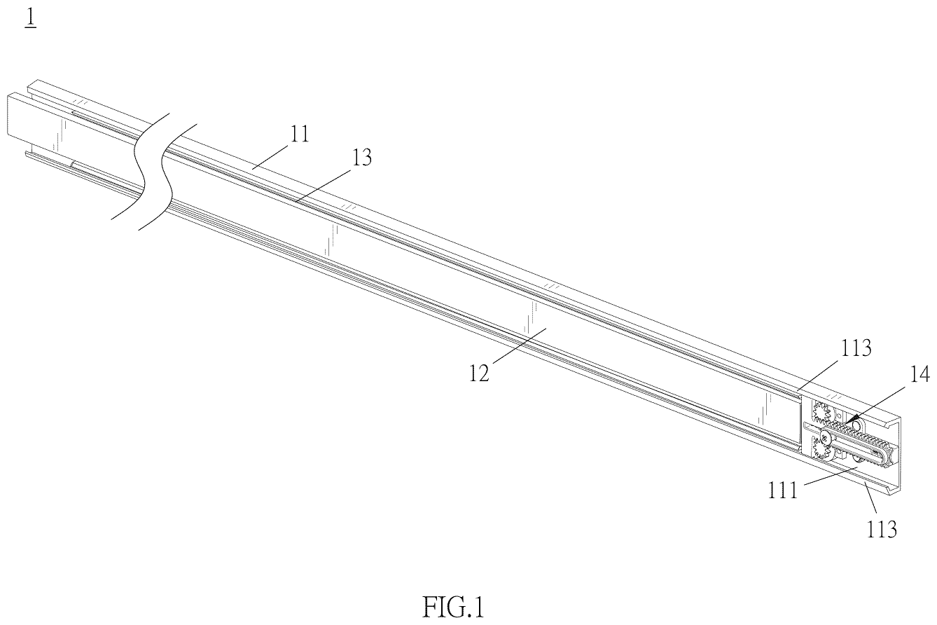

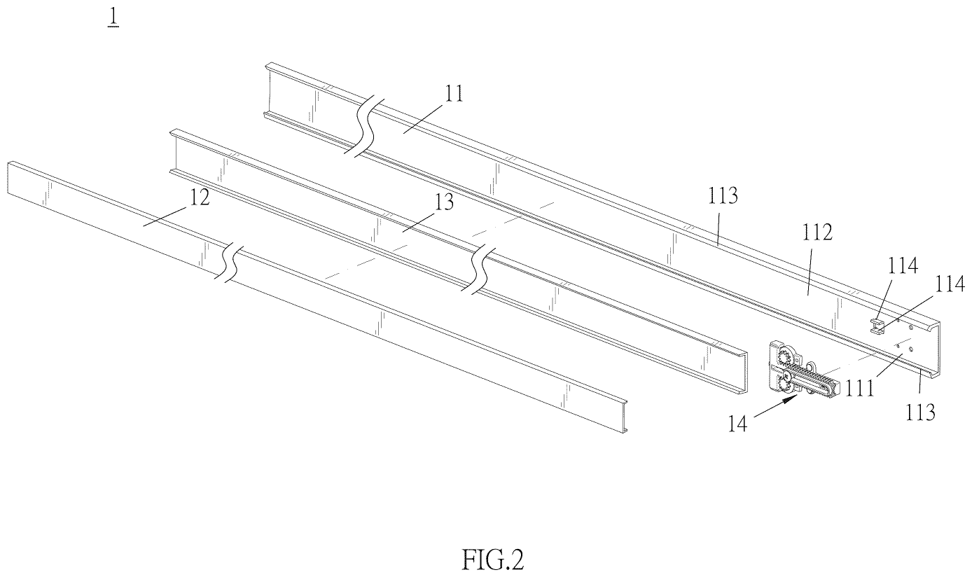

Referring to FIG. 1 and FIG. 2, the present invention is a slide rail assembly 1 comprising a first slide rail 11 (e.g., an outer frame), a second slide rail 12 (e.g., an inner frame), a third slide rail 13 (e.g., a middle frame), and a buffer device 14. The first slide rail 11 comprises a longitudinal wall 112, and two opposing bent portions 113 respectively inwardly bent from two opposite lateral sides of the longitudinal wall 112. The second slide rail 12 can be displaced relative to the first slide rail 11. The third slide rail 13 is movably installed between the second slide rail 12 and the first slide rail 11. The third slide rail 13 is used to extend the displacement length of the second slide rail 12 relative to the first slide rail 11. The structure, displacement, expansion and retraction of the second slide rail 12 and the third slide rail 13 are already known in the art and will not be further described for the sake of brevity.

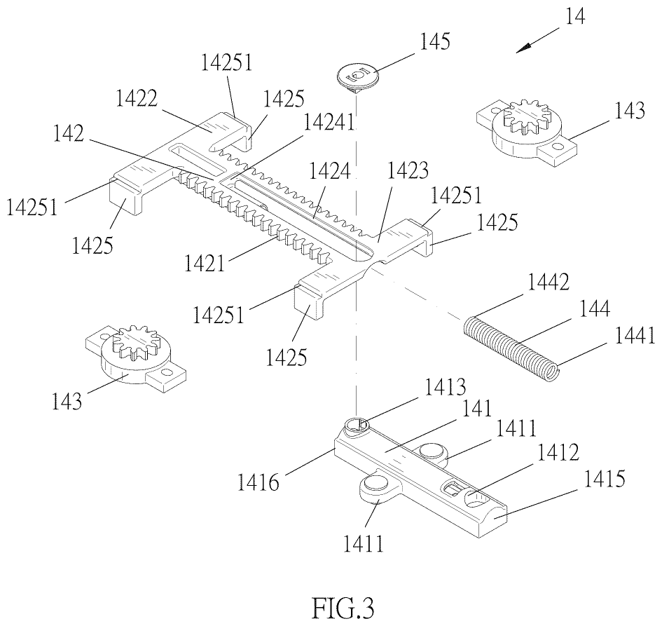

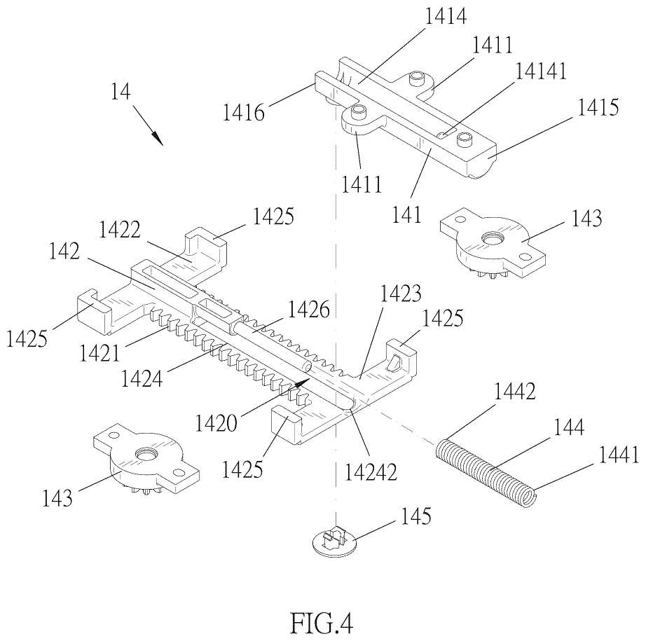

Referring to FIGS. 2-4, the buffer device 14 comprises a base 141, a slide 142, at least one movable member 143, a displacement member 144, and a locking member 145. The base 141 and the slide 142 are mutually connected. The base 141 and the at least one movable member 143 are respectively installed at one end 111 of the first slide rail 11. At least one side of the base 141 extends outwardly to form at least one fixing portion 1411, and the base 141 has a first end portion 1415 and a second end portion 1416. The first end portion 1415 is provided with a first fixing hole 1412, and the second end portion 1416 is provided with a second fixing hole 1413. The first fixing hole 1412 and the at least one fixing portion 1411 are respectively installed on the first slide rail 11. The displacement member 144 is provided between the base 141 and the slide 142. The base 141 is provided with a receiving groove 1414 from the second end portion 1416 toward the first end portion 1415 for accommodating the front end 1441 of the displacement member 144. The slide 142 comprises a third end portion 1422 and a fourth end portion 1423 on both sides, a hollow groove 1424 formed between the third end portion 1422 and the fourth end portion 1423, an elastic space 1420 formed below the hollow groove 1424 in which the rear end 1442 of the displacement member 144 is disposed, and a plurality of guide features 1421 formed on at least one of or both two opposite outer sides thereof between the third end portion 1422 and the fourth end portion 1423. The locking member 145 passes through the hollow groove 1424 and is then installed in the second fixing hole 1413 of the base 141. The third end portion 1422 and the fourth end portion 1423 are bent toward the longitudinal wall 112 and extend to form a respective support bar 1425. A respective recessed support portion 14251 is respectively provided at the bends between the third end portion 1422 and the fourth end portion 1423. A first connecting portion 1426 extends from the third end portion 1422 toward the fourth end portion 1423 and located below the hollow groove 1424. A second connecting portion 14141 is provided in the receiving groove 1414 of the base 141 corresponding to the first connecting portion 1426. The front end 1441 of the displacement member 144 of the buffer device 14 is set at the second connecting portion 14141, and the rear end 1442 of the displacement member 144 is set at the first connecting portion 1426.

The present invention is described with two movable members 143 as an example. The number of movable members 143 can be one, three, four or five. The embodiments are not intended to limit the patent scope of the present invention.

The present invention utilizes the displacement member 144 as a spring, hydraulic rod, pneumatic rod, or other component capable of returning to its original position after being compressed. The present invention is described using a spring (compression spring) as an example, and the example is not intended to limit the scope of the present invention.

The present invention has a plurality of guide features 1421 on the two opposite outer sides of the slide 142, and the at least one for example, two movable members 143 that are damping gears are used, and the plurality of guide features 1421 are series of teeth and the damping gears engage with the plurality of teeth. The locking member 145 is used as a rivet for the purpose of illustration only. The plurality of guide features 1421 may be disposed on at least one side between the two ends of the slide 142, and the locking member 145 may be a contour rivet, bolt, or other element with contour locking. The embodiments are not intended to limit the patent scope of the present invention.

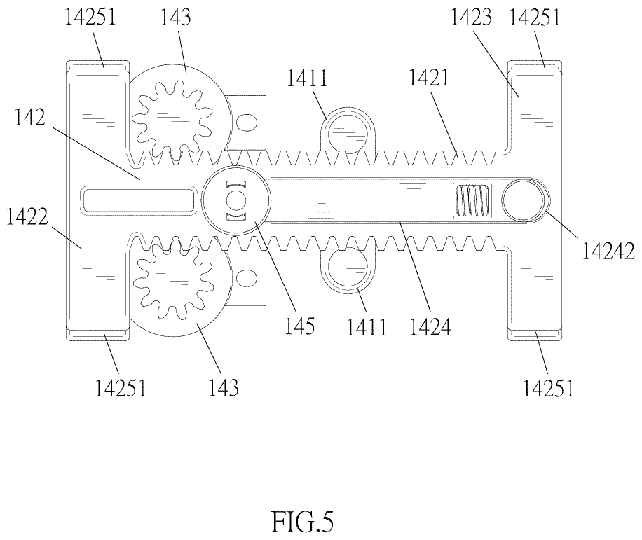

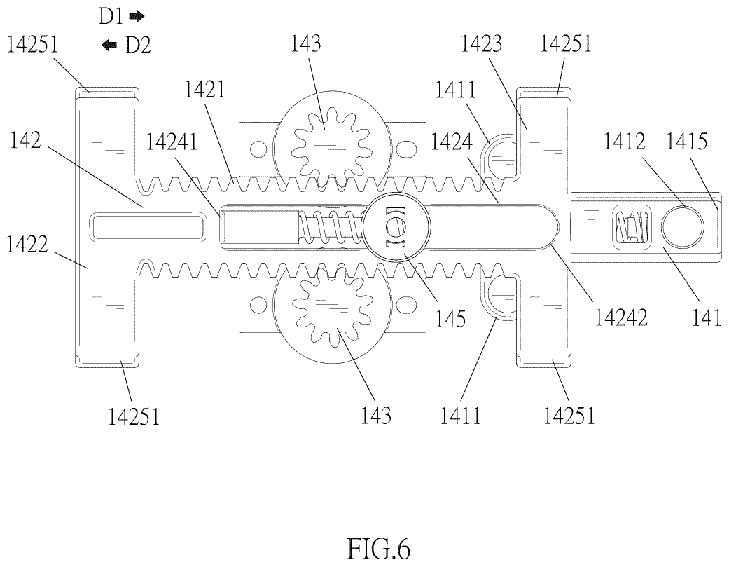

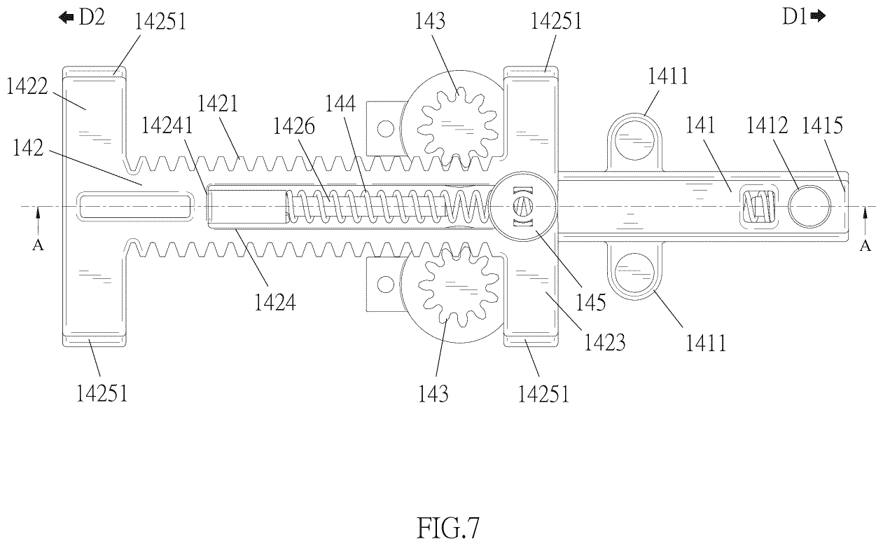

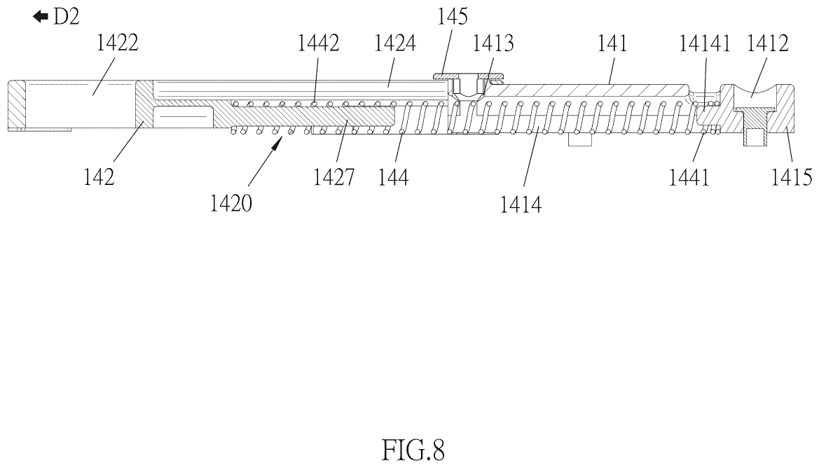

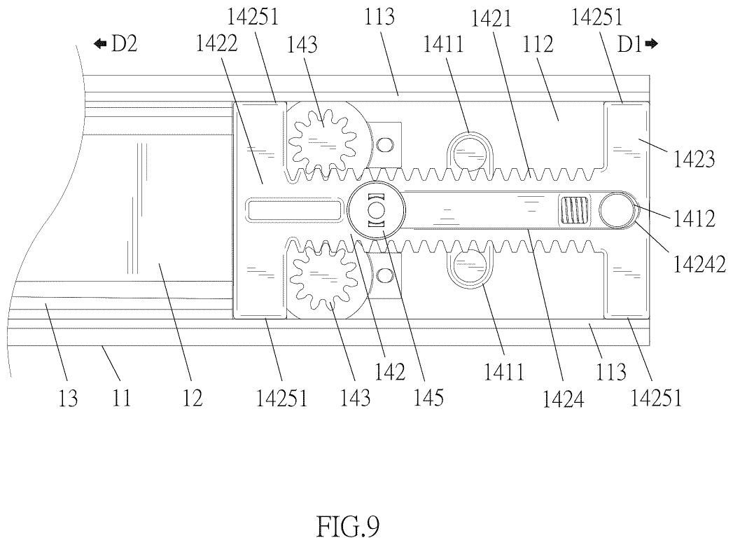

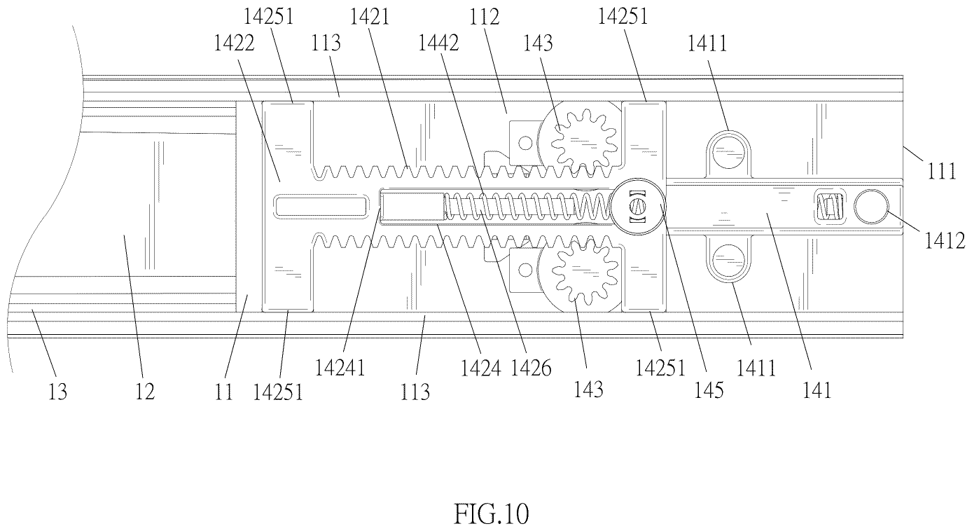

Please refer to FIGS. 5-10, wherein when folding, the second slide rail 12 is moved relative to the first slide rail 11 in a first direction D1 to the end of the stroke to abuts the third end portion 1422 of the slide 142, so that the second slide rail 12 and the slide 142 are moved synchronously in the first direction D1. The at least one movable member 143 abuts against the plurality of guide features 1421, and the slide 142 drives the displacement member 144 to be compressed, wherein the first connecting portion 1426 of the slide 142 compresses the rear end 1442 of the displacement member 144, and the second connecting portion 14141 of the base 141 compresses the front end 1441 of the displacement member 144. The third end portion 1422 and the fourth end portion 1423 of the slide 142 are connected to the recessed support portions 14251 of the support bars 1425 to abut against the bent portions 113 of the first slide rail 11, so that the displacement member 144 is compressed between the elastic space 1420 and the receiving groove 1414. At this time, the locking member 145 is pressed against the hollow groove rear end 14242 from the hollow groove front end 14241, so that the slide 142 and the base 141 are in a retracted state. The second slide rail 12 is slowly displaced relative to the first slide rail 11 in the first direction D1 by a thrust of the displacement member 144 and the at least one movable member 143 against the plurality of guide features 1421.

As above, when unfolding, the second slide rail 12 is moved relative to the first slide rail 11 in a second direction D2 opposite to the first direction D1, and the slide 142 and the base 141 are transformed from the retracted state to the expanded state. The second slide rail 12 separates from the third end portion 1422 of the slide 142, and the displacement member 144 extends to drive the slide 142 to move toward the second direction D2. The rear end 1442 of the displacement member 144 pushes against the first connecting portion 1426 of the slide 142, and the front end 1441 of the displacement member 144 pushes against the second connecting portion 14141 of the base 141, so that the displacement member 144 is expanded between the elastic space 1420 and the receiving groove 1414. At this time, the locking member 145 is pressed against the hollow groove front end 14241 by the hollow groove rear end 14242.

In accordance with the above, in another embodiment of the present invention, the at least one movable member 143 may be a rolling bearing (not shown in the figures), and the plurality of guide features 1421 may be a plurality of arc convex blocks (not shown in the figures). The rolling bearing presses the plurality of arc convex blocks. The at least one movable member 143 may be a component having one of the functions of rotating rapidly in the forward direction or slowly in the reverse direction. Its cooperating components, structure, and movement direction are the same as those described in the previous paragraph and will not be further elaborated here.

The buffer device 14 disclosed in the present invention comprises the base 141, the slide 142, the at least one movable member 143 and the displacement member 144. The base 141 and the slide 142 are connected to each other. The base 141 and the at least one movable member 143 are respectively mounted on one end 111 of the first slide rail 11, and at least one side of the slide 142 between the two ends thereof has a plurality of guide features 1421. The displacement member 144 is provided between the base 141 and the slide 142. By the thrust of the displacement member 144 and the at least one movable member 143 against the plurality of guide features 1421, before the second slide rail 12 reaches the end of the travel when it is retracted and displaced relative to the first slide rail 11, the second slide rail 12 abuts against the slide 142 of the buffer device 14, providing a buffering effect for the unidirectional slow displacement to the end of the travel. Furthermore, by installing the buffer device 14 at one end 111 of the first slide rail 11, the modular design of the buffer device 14 allows the components that form the buffering function to be concentrated in one place, thereby improving installation efficiency and facilitating maintenance and replacement.

What the invention claimed is:

1. A buffer device, comprising:
a base;
a slide coupled to said base, said slide comprising a plurality of guide features on at least one side between two ends thereof;
a displacement member set between said base and said slide; and
at least one movable member located on one side of said slide;
wherein: when said slide is displaced in a first direction by a force, said slide compresses said displacement member, and said slide and said base are in a retracted state, and said slide is displaced slowly by a thrust of said displacement member and said at least one movable member against said plurality of guide features; when said slide is extended and pushed by said displacement member, said slide and said base are put into an expanded state through the pushing force of said displacement member, so that said slide is quickly displaced in a second direction opposite to said first direction.

2. The buffer device as claimed in claim 1, wherein said at least one movable member each is a damping gear, said plurality of guide features are a series of teeth, and said at least one damping gear engages with said series of teeth.

3. The buffer device as claimed in claim 1, wherein said at least one movable member each is a rolling bearing, said plurality of guide features are arc convex blocks, and said at least one rolling bearing presses and engages said plurality of arc convex blocks.

4. The buffer device as claimed in claim 1, wherein said at least one movable member each is a component having one of the functions of rotating rapidly in the forward direction or rotating slowly in the reverse direction.

5. The buffer device as claimed in claim 1, wherein said displacement member is selectively one of a spring, a hydraulic rod or a pneumatic rod.

6. The buffer device as claimed in claim 1, wherein said base comprises at least one fixing portion extending outwardly from at least one of two opposite lateral sides thereof, a first end portion, an opposing second end portion, a first fixing hole located on said first end portion, a second fixing hole located on said second end portion, and a receiving groove extending from said second end portion toward said first end portion for a front end of said displacement member to be disposed.

7. The buffer device as claimed in claim 1, wherein said slide further comprises a third end portion and a fourth end portion on two sides thereof, two support bars respectively bent from said third end portion and said fourth end portion in the same direction, and a recessed support portion respectively provided at the bends between said third end portion and said fourth end portion.

8. The buffer device as claimed in claim 7, wherein said slide further comprises a hollow groove disposed between said third end portion and said fourth end portion, and an elastic space formed below said hollow groove for said displacement member to be disposed.

9. The buffer device as claimed in claim 8, wherein said slide further comprises a first connecting portion extending from said third end portion toward said fourth end portion and located below said hollow groove; said base further comprises a second connecting portion provided in said receiving groove corresponding to said first connecting portion; said displacement member has a front end thereof set at said second connecting portion and an opposing rear end thereof set at said first connecting portion so that said displacement member to compress and stretch in said receiving groove and said elastic space.

10. The buffer device as claimed in claim 9, further comprising a locking member, said locking member passed through said hollow groove and installed on said base to restrict said displacement member to said elastic space.

11. A slide rail assembly, comprising:
a first slide rail and a second slide rail displaceable relative to said first slide rail; and
a buffer device, comprising a base, a slide, at least one movable member and a displacement member, said base and said slide being coupled to each other, said base and said at least one movable member being respectively installed at one end of said first slide rail, said slide comprising a plurality of guide features on at least one side between two ends thereof, said displacement member being set between said base and said slide;
wherein: when said second slide rail moves relative to said first slide rail in a first direction, said second slide rail abuts against said slide to displace said slide, so that said slide drives said displacement member to compress, said slide and said base are in a retracted state, and said second slide rail is displaced slowly by a thrust of said displacement member and said at least one movable member against said plurality of guide features; when said second slide rail is displaced relative to said first slide rail in a second direction opposite to said first direction, said displacement member is extended, so that said slide and said base are in an expanded state, and said second slide rail is separated from said slide.

12. The slide rail assembly as claimed in claim 11, wherein said at least one movable member each is a damping gear, said plurality of guide features are a series of teeth, and said at least one damping gear engages with said series of teeth.

13. The slide rail assembly as claimed in claim 11, wherein said at least one movable member each is a rolling bearing, said plurality of guide features are arc convex blocks, and said at least one rolling bearing presses and engages said plurality of arc convex blocks.

14. The slide rail assembly as claimed in claim 11, wherein said at least one movable member each is a component having one of the functions of rotating rapidly in the forward direction or rotating slowly in the reverse direction.

15. The slide rail assembly as claimed in claim 11, wherein said displacement member is selectively one of a spring, a hydraulic rod or a pneumatic rod.

16. The slide rail assembly as claimed in claim 11, wherein said base comprises at least one fixing portion extending outwardly from at least one of two opposite lateral sides thereof, a first end portion, an opposing second end portion, a first fixing hole located on said first end portion, a second fixing hole located on said second end portion, and a receiving groove extending from said second end portion toward said first end portion for a front end of said displacement member to be disposed.

17. The slide rail assembly as claimed in claim 11, wherein said first slide rail comprises a longitudinal wall, and two opposing bent portions respectively inwardly bent from two opposite lateral sides of said longitudinal wall; said slide further comprises a third end portion and a fourth end portion on two sides thereof, two support bars respectively bent from said third end portion and said fourth end portion in the same direction, and a recessed support portion respectively provided at the bends between said third end portion and said fourth end portion resting against one respective said bent portion.

18. The slide rail assembly as claimed in claim 17, wherein said slide further comprises a hollow groove disposed between said third end portion and said fourth end portion, and an elastic space formed below said hollow groove for said displacement member to be disposed.

19. The slide rail assembly as claimed in claim 18, wherein said slide of said buffer device further comprises a first connecting portion extending from said third end portion toward said fourth end portion and located below said hollow groove; said base of said buffer device further comprises a second connecting portion provided in said receiving groove corresponding to said first connecting portion; said displacement member of said buffer device has a front end thereof set at said second connecting portion and an opposing rear end thereof set at said first connecting portion so that said displacement member to compress and stretch in said receiving groove and said elastic space.

20. The slide rail assembly as claimed in claim 19, wherein said buffer device further comprises a locking member passed through said hollow groove and installed on said base to restrict said displacement member to said elastic space.
